(19) United States
(12) Patent Application Publication
(10) Pub. No.: US 2014/0377534 A1
(43) Pub. Date: Dec. 25, 2014

(54) CIRCUIT SUBSTRATE AND MANUFACTURING METHOD THEREOF

(71) Applicant: SHENGYI TECHNOLOGY CO., LTD., Dongguan City, Guangdong (CN)

(72) Inventors: Minshe Su, Dongguan City (CN); Qianfa Liu, Dongguan City (CN)

(21) Appl. No.: 14/368,437

(22) PCT Filed: Dec. 29, 2011
(86) PCT No.: PCT/CN2011/084870

§ 371 Date: Sep. 9, 2014

(51) Int. Cl. H05K 1/02; H05K 3/46; H05K 1/03

(52) U.S. Cl. CPC H05K 1/0271; H05K 1/0306; H05K 3/4611; H05K 2201/0137
USPC 428/317.7; 428/317.1; 156/306.9; 156/252; 216/33

(57) ABSTRACT

A circuit substrate, including a porous glass film with the volume percentage ratio of the glass being above 45%, a resin adhesion layer located on either side of the glass film respectively, and a metal foil located in the outside of resin adhesion layer. The glass film, the resin adhesion layer and the metal foil join together through suppressing, and the resin of the resin adhesion layer is filled in the gaps of the glass film. The circuit substrate employs a porous glass film as a carrier material, so that the resin adhesion layer and the surface of the glass film surface have a good binding force, and the CTE of the circuit substrate in the direction of X and Y is reduced compared to instances before, and has good formability, which is simple and convenient in process operation. In addition, also provided is a manufacturing method for a circuit substrate.

### TECHNICAL FIELD

The present invention relates to a circuit substrate for a printed circuit and manufacturing method thereof.

### BACKGROUND ART

In recent years, with the development of the electronic products towards multi-function and miniaturization, and the development of the circuit substrate used towards multi-layer, high-density of wiring, high modulus and high-speed signal transmission, there is higher requirement for comprehensive performance of circuit substrate, that is, metal clad laminate, such as copper clad laminate.

For example, with the increase of the circuit interconnection density of the electronic products, the requirements for the circuit substrate's dimensional stability become higher and higher. In order to reduce the thermal stress produced during the thermal shock in the process of making circuit substrates and meet precise hole-alignment of components during the installation and assembly, CTE (Coefficient of Thermal Expansion) in X, Y, Z direction of the circuit substrate (respectively referring to the length, width and thickness direction of the circuit substrate) is required to be as small as possible. Particularly, for the circuit substrate for IC packages, CTE in X, Y direction should be as close to that of silicon chips (3 ppm/° C.) as possible, because the chips can be damaged by the strong stress-strain produced during the environmental cold-thermal shock if the difference between CTE of the circuit substrate and CTE of the chip packaged therein is too large.

The currently used copper clad laminate (FR-4) usually uses glass fiber fabric as enhancement material. Nevertheless, as the glass fiber fabric is limited by manufacturing process, the woven material has a high pore ratio. Due to the ratio of the glass fiber fabric to resin in the cooper clad laminate (glass accounts for less than 45% by volume based on the sum of the glass fiber fabric and the resin), CTE of copper clad laminate along X or Y direction is between 16-18 ppm/° C.

To improve the above-mentioned properties, U.S. Patent Application 20040037950A1 used thin glass film to replace the glass fiber fabric for the manufacture of copper clad laminate. Said patent application disclosed a multi-layer board structure was composed of a glass film, a resin layer and a copper layer, however, it did not disclose how to get good adhesion between the surface of the glass film and the resin layer. The surface of the glass film is smooth, thus the resin layer cannot form good binding force with it, thereby the copper wire adhered to the resin layer is easy to peel off from the glass film together with the resin layer. This further causes that the copper clad laminate manufactured by this method has low reliability during PCB fabrication, PCB element assembly and use of electronic products, leading to destroy of electronic products.

### SUMMARY OF THE INVENTION

The object of the present invention is to provide a circuit substrate, wherein a porous glass film is used as carrier material, causing the resin adhesion layer has good binding force with the glass film surface.

Another object of the circuit present invention is to provide a circuit substrate manufactured by using the porous glass film, wherein the number of pores in the glass film is controlled to make the glass accounts for more than 45% in volume based the whole glass film, causing the CTE in either X or Y direction of the circuit substrate reduced compared with prior art.

A further object of the present invention is to provide a method for manufacturing a circuit substrate, wherein a porous glass film is used as the carrier material. The method has good formability and convenient operation.

To achieve the above-mentioned objects, the present invention provides a circuit substrate, comprising a porous glass film wherein glass accounts for more than 45% by volume, resin adhesion layers located on both sides of the glass film, and metal foils located outside of the resin adhesion layer, wherein the glass film, the resin adhesion layer and the metal foil are combined together by pressing and wherein the resin of the resin adhesion layer is filled with the pores in the glass film.

In the glass film, the glass accounts for 45% to 90% by the volume.

Preferably, the glass accounts for 65% to 80% by volume in the glass film.

The glass composition of the glass film is an aluminosilicate glass with less than 0.3% (by weight) of the alkali metal oxide or a boron silicate glass with less than 0.3% (by weight) of the alkali metal oxide.

The thickness of the glass film is from 20 μm to 1.1 mm

The pores in the glass film distribute evenly, and the pore diameter is from 20 μm to 300 μm.

The surface of the glass film has been treated by roughening.

The resin of the resin adhesion layer is one or more selected from the group consisting of epoxy resin, cyanate ester resin, phenolic resin, polyphenylene ether resin, polybutadiene resin,polybutadiene-styrene copolymer resin, polytetrafluoroethylene resin, polybenzoxazine resin, polyimide, silicon resin, bismaleimide triazine resin, LCP resin, and bismaleimide resin.

The resin adhesion layer comprises a powder filler, which is one or more selected from the group consisting of crystalline silica, fused silica, spherical silica, strontium titanate, barium titanate, barium strontium titanate, boron nitride, aluminium nitride, silicon carbide, aluminum oxide, titanium dioxide, glass powder, chopped glass fibers, talc powder, mica powder, conductex, carbon nanotube, metal powder, polyphenylene sulfide and PTFE pwder, wherein the median value of the particle size of the powder filler is 0.01-15 μm, preferably 0.5-10 μm.

The present invention also provides a manufacturing method of the circuit substrate, which comprises the following steps:
Step 1: providing a porous glass film wherein glass accounts for more than 45% by volume;
Step 2: laminating one or more prepregs on both sides of the glass film separately;
Step 3: laminating one metal foil on the side of each prepreg against the glass film separately;
Step 4: putting the laminated layers into a presser machine for hot pressing at a curing temperature ranging from 100° C. to 400° C. and a curing pressure ranging from 10 Kg/cm² to 65 Kg/cm², to obtain the circuit substrate.

In the above-mentioned manufacturing method, the pores distribute evenly in the glass film, and the pore diameter is from 20 μm to 300 μm. The pores are processed to form in the manner of laser or mechanical/chemical selective etching.

The present invention also provides another manufacturing method of the circuit substrate, which comprises the following steps:
Step 1: providing a porous glass film wherein glass accounts for more than 45% by volume;
Step 2: laminating one resin-coated metal foil on each side of the glass film separately;
Step 3: putting the laminated layers into the presser machine for hot pressing at a curing temperature ranging from 100° C.˜400° C. and a curing pressure ranging from 10 Kg/cm²˜65 Kg/cm², to obtain the circuit substrate.

In the above-mentioned manufacturing method, the pores distribute evenly in the glass film, and the pore diameter is from 20 μm to 300 μm. The pores are processed to form in a manner of laser or mechanical/chemical selective etching.

The advantages of the present invention are:
first, using a porous glass film as carrier material make the adhesion layer has good binding force with the glass film surface, because the resin can enter the pores of the glass film and plays the role of pins;
second, controlling the number of pores in the glass film to make the glass accounts for more than 45% by volume based on the whole glass film, causing the CTEs in X, Y and Z directions of the circuit substrate reduced compared with the copper clad laminate using glass fiber fabric as reinforcing material in the prior art;
third, the manufacturing process of the circuit substrate of the present invention is simple and thus easy to apply to a large-scale production.

In order to further illustrate the technical means for achieving the intended object and the effects, the present invention will be described below by referring to the detailed description and the accompanying drawings, from which the objects, features and characters of the invention will be deeply and specifically understood. It should be noted that the accompanying drawings are only for reference and explaining, not making any limit to the invention.

### BRIEF DESCRIPTION OF THE DRAWINGS

The technical solutions of the present invention and the beneficial effects thereof will be clear by describing the specific embodiments in detail referring to the accompanying drawings.

Wherein,

FIG. 1 is a structural diagram of a circuit substrate of the present invention

### DETAILED DESCRIPTION

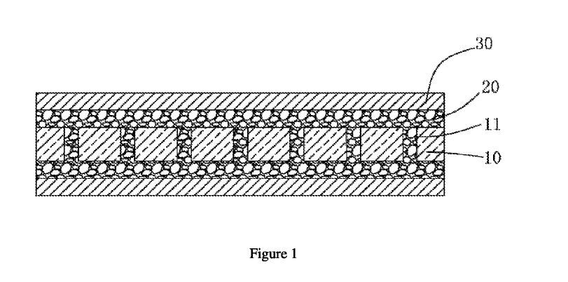

As FIG. 1 shows, the circuit substrate of the present invention comprises the porous (11) glass film (10) wherein glass accounts for more than 45% by volume based on the whole glass film, the resin adhesion layers (20) separately located on both sides of the glass film (10) and the metal foils (30) located outside of resin adhesion layers (20), wherein said glass film (10), said resin adhesion layer (20) said the metal foil (30) are bonded together by press, and the resin of the resin adhesion layer (20) filled in the pores (11) of the glass film (10).

As used herein, the term “glass accounts for . . . % by volume” refers to the ratio of the volume of the glass to the sum volume of the pores (11) and the glass in the glass film (10).

Preferably, the glass accounts for 45% to 90% by volume in the glass film. When the glass accounts for more than 90% by volume, there are too little resins filled with the pores (11) in the glass film (10), without a good result of optimizing peel strength; however, when the glass accounts for less than 45% by volume, there are too many resins filled with the pores (11) in the glass film (10), without a good result of optimizing CTEs in X, Y and Z directions.

The resins in the adhesion layer (20) is one or more selected from the group consisting of epoxy resin, cyanate ester resin, phenolic resin, polyphenylene ether resin, polybutadiene resin,polybutadiene-styrene copolymer resin, polytetrafluoroethylene resin, polybenzoxazine resin, polyimide, silicon resin, bismaleimide triazine resin (BT resin), LCP (Liquid Crystal Polymer) resin, and bismaleimide resin.

Preferably, the glass composition of the glass film (10) is aluminosilicate glass with less than 0.3% (by weight) of the alkali metal oxide taking or a boron silicate glass with less than 0.3% (by weight) of the alkali metal oxide taking.

The thickness of the glass film (10) can be selected from the range from 20 μm to 1.1 mm.

The pores (11) distribute evenly in the glass film (10), and the pore diameter is from 20 μm to 300 μm. The pores are processed to form in a manner of laser or mechanical/chemical selective etching.

In order to obtain a better binding force between the glass film (10) and the resin, the surface of the glass film (10) can also be roughened by one or more methods sleeted from the group consisting of brushing, chemical etching, frosting, sol-gel method and mechanical polishing. As such, the contact area can be enlarged and the glass film (10) and the resin can bind better.

The above-mentioned resin adhesion layer (20) may also comprise powder filler, which plays roles of improving the dimensional stability, reducing CTE, etc. The above-mentioned resin adhesion layer (20) may also comprise fluoropolymer with low dielectric loss, wherein said powder filler accounts for 0-70% by volume based on the sum of the powder filler and the fluoropolymer. The powder filler is one or more selected from the group consisting of crystalline silica, fused silica, spherical silica, strontium titanate, barium titanate, strontium barium titanate, boron nitride, aluminium nitride, silicon carbide, aluminum oxide, titanium dioxide, glass powder, chopped glass fibers, talc powder, mica powder, conductex, carbon nanotube, metal powder, polyphenylene sulfide and PTFE. Preference is given to fused silica or titanium dioxide. For the convenience of the powder filler entering the pores (11) in the glass film (10), the median value of the particle size of the powder filler is 0.01-15 μm. Preferably, the median value of the particle size of the powder filler is 0.5-10 μm. To achieve better performance, the surface of the powder filler can be treated, for example, by coupling agent and the like. Said resin adhesion layer (20) also comprises aids, including emulsifying agents and dispersing agents.

Said metal foil (30) is copper, aluminium or nickel, or alloys thereof.

The above mentioned circuit substrate may be manufactured in many ways. One method for manufacturing the circuit substrate comprises the following steps:
Step 1: providing a porous glass film wherein glass accounts for more than 45% by volume;
Step 2: laminating one or more prepregs on both sides of the glass film separately;
Step 3: laminating one metal foil on the side of each prepreg against the glass film separately;
Step 4: putting the laminated layers into the presser machine for hot pressing at a curing temperature ranging from 100° C.˜400° C. and a curing pressure ranging from 10 Kg/cm²˜65 Kg/cm², to obtain the circuit substrate.

In this manufacturing method, the volume percentage of the glass is preferably 45% to 90%.

In this manufacturing method, the pores distribute evenly in the glass film, and the pore diameter is 20 μm to 300 μm. The pores are processed to form in a manner of laser or mechanical/chemical etching.

In the step 1 of this manufacturing method, it also comprises roughing processing to the surface of the glass film.

In this manufacturing method, said prepreg is manufactured by impregnating glass fiber fabric into resin. Said resin is one or more selected from the group consisting of epoxy resin, cyanate ester resin, a phenol resin, a polyphenylene ether resin, allyl resin, polybutylene resin, polybutadiene and styrene copolymer resin, polytetrafluoroethylene resin, polybenzoxazine resin, a polyimide, a silicon resin, a bismaleimide triazine resin (BT resin), LCP (Liquid Crystal Polymer) resin and bismaleimide resin.

Another manufacturing method of the above mentioned circuit substrate comprises the following steps:
Step 1: providing a porous glass film wherein glass accounts for more than 45% by volume based on the whole glass film;

Step 2: laminating one resin-coated metal foil on each side of the glass film separately;

Step 3: putting the laminated layers into the presser machine for hot pressing at a curing temperature ranging from 100° C.˜400° C. and a curing pressure ranging from 10 Kg/cm²˜65 Kg/cm² to obtain the circuit substrate. Wherein, the resin on the resin-coated metal foil is pressed to form the resin adhesion layer.

In the above mentioned manufacturing method, the volume percentage of the glass is preferably 45% to 90%.

In the above manufacturing method, the pores distribute evenly in the glass film, and the pore diameter is 20 μm to 300 μm. The pores are processed to form in a manner of laser or mechanical/chemical etching processing.

In the step 1 of this manufacturing method, it also comprises roughing processing to the surface of the glass film.

In this manufacturing method, said resin-coated metal foil is manufactured by coating the resin on the metal foil. Said resin is one or more selected from the group consisting of epoxy resin, cyanate ester resin, phenolic resin, polyphenylene ether resin, polybutadiene resin,polybutadiene-styrene copolymer resin, polytetrafluoroethylene resin, polybenzoxazine resin, polyimide, silicon resin, bismaleimide triazine resin, LCP resin, and bismaleimide resin.

The above mentioned circuit substrate is further described referring to the following examples:

### EXAMPLE 1

Take a porous glass film with thickness of 200 μm, pore diameter of 100 μm, and glass volume percentage of 65% (dried and pre-treated with a coupling agent), on each side of the glass film put a FR4 prepreg (that is, prepreg used for S1141 copper clad laminate of Guangdong Shengyi Sci. Tech Co., Ltd.) manufactured by impregnating a glass fibre fabric having a thickness of 0.1 mm (2116 glass fibre fabric) into epoxy resin glue system (dicyandiamide curing agent) and conduct laminating; then on each sides put a copper foil and conduct laminating again.

Put the above-mentioned laminated layers into a presser machine at a curing temperature of 180° C. and a curing pressure of 15 Kg/cm² in vacuum. Conduct hot pressing to obtain a circuit substrate (that is, copper clad laminate). Test the circuit substrate: the peel strength between the copper foil and the prepreg is 1.7 N/mm and that between the prepreg and the glass film is 1.2 N/mm; the CTEs before reaching the glass-transition temperature is 8.2 ppm/° C. and 7.8 ppm/° C. in X and Y directions, separately.

### EXAMPLE 2

Take a porous glass film with thickness of 50 μm, pore diameter of 20 μm, and glass volume percentage of 80% (dried and pre-treated with a coupling agent), on each side of the glass film put a FR4 prepreg (that is, prepreg used for S1141 copper clad laminate of Guangdong Shengyi Sci. Tech Co., Ltd.) manufactured by impregnating a glass fibre fabric having a thickness of 0.06 mm (1080 glass fibre fabric) into epoxy resin glue system and conduct laminating; then on each sides put a copper foil and conduct laminating again.

Put the above-mentioned laminated layers into a presser machine at a curing temperature of 180° C. and a curing pressure of 15 Kg/cm² in vacuum. Conduct hot pressing to obtain a circuit substrate (that is, copper clad laminate). Test the circuit substrate: the peel strength between the copper foil and the prepreg is 1.7 N/mm and that between the prepreg and the glass film is 0.8 N/mm; the CTEs before reaching the glass-transition temperature is 7.1 ppm/° C. and 6.8 ppm/° C. in X and Y directions, separately.

### EXAMPLE 3

Take a porous glass film with thickness of 1 mm, pore diameter of 200 μm, and glass volume percentage of 50% (dried and pre-treated with a coupling agent), on each side of the glass film put a FR4 prepreg (that is, prepreg used for S1141 copper clad laminate of Guangdong Shengyi Sci. Tech Co., Ltd.) manufactured by impregnating a glass fibre fabric having a thickness of 0.06 mm (1080 glass fibre fabric) into epoxy resin glue system (dicyandiamide curing agent) and conduct laminating; then on each sides put a copper foil and conduct laminating again.

Put the above-mentioned laminated layers into a presser machine at a curing temperature of 180° C. and a curing pressure of 25 Kg/cm² in vacuum. Conduct hot pressing to obtain a circuit substrate (that is, copper clad laminate). Test the circuit substrate: the peel strength between the copper foil and the prepreg is 1.75 N/mm and that between the prepreg and the glass film is 0.9 N/mm; the CTEs before reaching the glass-transition temperature is 12.6 ppm/° C. and 12.3 ppm/° C. in X and Y directions, separately.

### Comparison Example 1

Impregnate five glass fibre fabrics with thickness of 0.1 mm (2116 glass fibre fabric) into epoxy resin glue system (dicyandiamide curing agent) to obtain FR4 prepreg (that is, prepreg used for S1141 copper clad laminate in Guangdong Shengyi Sci. Tech Co., Ltd.) and conduct laminating. Then on each side put a copper foil and conduct laminating again.

Put the laminated layers into a presser machine wherein the curing temperature is 180° C. and the curing pressure is 25 Kg/cm² in vacuum. Conduct hot pressing to obtain a circuit substrate (that is, copper clad laminate). Test the circuit substrate: the peel strength between the resin layer and the glass film is 1.75 N/mm; the CTEs before reaching the glass-transition temperature are 17.6 ppm/° C. and 17.3 ppm/° C. in X and Y directions, respectively.

### Comparison Example 2

Take a porous glass film with thickness of 60 μm, on each side of the glass film put a FR4 prepreg (that is, prepreg used for S1141 copper clad laminate of Guangdong Shengyi Sci. Tech Co., Ltd.) manufactured by impregnating a glass fibre fabric having a thickness of 0.1 mm (2116 glass fibre fabric) into epoxy resin glue system (dicyandiamide curing agent) and conduct laminating; then on each sides put a copper foil and conduct laminating again.

Put the laminated layers into a presser machine wherein the curing temperature is 180° C. and the curing pressure is 15 Kg/cm² in vacuum. Conduct hot pressing to obtain a circuit substrate (that is copper clad laminate). Test the circuit substrate: the copper foil adheres to the prepreg but peel off from the glass film, showing the peel strength is 0.1 N/mm; the CTEs before reaching the glass-transition temperature are 6.8 ppm/° C. and 7.3 ppm/° C. in X and Y directions, respectively.

As can be known from Examples 1-3, the circuit substrates manufactured from the porous glass film not only reduce CTE of circuit substrate in X, Y direction, but have good peel strength. Meanwhile, the examples disclose when the volume percentage of glass is 45˜90% and the pore diameter is 20 μm˜30 μm, good peel strength and good CTEs in X and Y direction can be obtained at the same time.

As can be known from Comparison Example 1, CTEs of the traditional FR-4 copper clad laminate in X and Y directions are apparently higher than those of Examples 1-3, because it uses glass fibre fabric as the reinforcing material, does not use the glass film which can improve glass percentage in copper clad laminate.

As can be known from Comparison Example 2, the copper clad laminate can peel off easily and has limited usefulness because of no using porous glass film.

### EXAMPLE 4

Take a porous glass film with thickness of 1 mm, pore diameter of 200 μm, and glass volume percentage of 50% (dried and pre-treated with a coupling agent), on each side of the glass film put a resin-coated copper (RCC) coated by epoxy resin with thickness of 50 μm and conduct laminating.

Put the laminated layers into a presser machine wherein the curing temperature is 180° C. and the curing pressure is 15 Kg/cm² in vacuum. Conduct hot pressing to obtain a circuit substrate (that is copper clad laminate). Test the circuit substrate: the peel strength between the resin layer and the glass film is 1.8 N/mm; the CTE before reaching the glass-transition temperature is 8.6 ppm/° C. in either X or Y direction.

### EXAMPLE 5

Take a porous glass film with thickness of 1 mm, pore diameter of 200 μm, and glass volume percentage of 50% (dried and pre-treated with a coupling agent), on each side of the glass film put a resin-coated copper (RCC) coated by epoxy resin glue system (wherein the resin layer contains silicon micro-powder of 20% by volume) with thickness of 50 μm and conduct laminating.

Put the laminated layers into a presser machine wherein the curing temperature is 180° C. and the curing pressure is 15 Kg/cm² in vacuum. Conduct hot pressing to obtain a circuit substrate (that is copper clad laminate). Test the circuit substrate: the peel strength between the resin layer and the glass film is 1.3 N/mm; the CTE before reaching the glass-transition temperature is 6.6 ppm/° C. in either X or Y direction.

### EXAMPLE 6

To a 1 L 3-neck-flask add 750 g of solvent N-methyl-pyrrolidone(NMP), add 82.1 g of 2, 2′- bis-[4-(4-amino phenoxy) phenyl] propane, put the flask into a water bath for cooling, purge nitrogen for protecting, after 30 minutes, add 59.43 g of biphenyl tetracarboxylic dianhydrid, stir 3 hours in high speed to conduct a polymerization reaction, obtaining a polyimide precursor solution with viscosity of 600 mPa·s. The polyimide precursor solution is a thermoplastic polyimide precursor solution.

Apply the obtained thermoplastic polyimide precursor solution on the rough surface of the copper foil with coating thickness of 14 μm, and bake for 5 minutes under 220° C. to make it into a resin-coated copper. Take a porous glass film with thickness of 50 μm, pore diameter of 20 μm, and glass volume percentage of 65% (dried and pre-treated with a coupling agent), put one piece of the resin-coated copper on each side of the glass film and conduct laminating by putting into a high temperature presser machine. The program of pressing is as follows: increasing the temperature to 250° C. over 1 hour, and maintain at 250° C. for 30 minutes, then increasing the temperature to 350° C. over 1 hour, and maintain at 250° C. for 30 minutes; after 2 hours, decreasing the temperature to room temperature, then opening the presser machine and take out the copper clad laminate. Once the pressing program starts, draw a vacuum and apply a surface pressure of 5 MPa.

Test the obtained circuit substrate: the peel strength between the resin layer and the glass film is 1.3 N/mm; CTE before reaching the glass-transition temperature is 6.8 ppm/° C. in either X or Y direction.

In Example 4, the circuit substrate is manufactured by corporately using a resin-coated copper foil and a porous glass film, obtaining good peel strength and low CTE in either X or Y direction.

In Example 5, the circuit substrate is manufactured by corporately using a resin-coated copper foil wherein the resin layer is added with powder filler and a porous glass film, further decreasing the CTE in either X or Y direction compared with Example 4.

In Example 6, the circuit substrate is manufactured by corporately using resin-coated copper foil of polyimide and a porous glass film, also obtaining good peel strength and low CTE in either X or Y direction.

The circuit substrates manufactured in the above manners not only can be used as base material of a circuit board but also can used for optical waveguide path.

Those skilled in the art can make numerous modifications and changes according to the technical solution and spirit of the present invention, all of which fall into the protected scope as prescribed by the claims of the present application.

1. A circuit substrate, comprising a porous glass film wherein glass accounts for more than 45% by volume, resin adhesion layers located on both sides of the glass film, and the metal foils located outside of the resin adhesion layer, wherein the glass film, the resin adhesion layer and the metal foil are combined by pressing and wherein the resin of the resin adhesion layer is filled with the pores of the glass film.

2. The circuit substrate according to claim 1, wherein the glass accounts for 45% to 90% by volume based on the glass film.

3. The circuit substrate according to claim 1, wherein the glass accounts for 65% to 80% by volume based on the glass film.

4. The circuit substrate according to claim 1, wherein the glass composition of the glass film is aluminosilicate glass with the alkali metal oxide accounting for less than 0.3% by weight or boron silicate glass with the alkali metal oxide accounting for less than 0.3% by weight.

5. The circuit substrate according to claim 1, wherein thickness of the glass film is from 20 μm to 1.1 mm.

6. The circuit substrate according to claim 1, wherein the pores are distributed evenly in the glass film and the pore diameter is from 20 μm to 300 μm.

7. The circuit substrate according to claim 1, wherein the surface of the glass film is treated by roughening.

8. The circuit substrate according to claim 1, wherein the resin of the resin adhesion layer is one or more selected from the group consisting of epoxy resin, cyanate ester resin, phenolic resin, polyphenylene ether resin, polybutadiene resin, polybutadiene-styrene copolymer resin, polytetrafluoroethylene resin, polybenzoxazine resin, polyimide, silicon resin, bismaleimide triazine resin, LCP resin, and bismaleimide resin.

9. The circuit substrate according to claim 1, wherein the resin adhesion layer comprises a powder filler, which is one or more selected from he the group consisting of crystalline silica, fused silica, spherical silica, strontium titanate, barium titanate, strontium barium titanate, boron nitride, aluminium nitride, silicon carbide, aluminum oxide, titanium dioxide, glass powder, chopped glass fibers, talc powder, mica powder, conductex, carbon nanotube, metal powder, polyphenylene sulfide and PTFE, wherein the median value of the particle size of the powder filler is 0.01-15 μm.

10. The manufacturing method of the circuit substrate according to claim 1, wherein the manufacturing method comprises the following steps:
providing a porous glass film wherein glass accounts for more than 45% by volume;
laminating one or more prepregs on each side of the glass film separately;
laminating one metal foil on the side of each prepregs against the glass film separately;
putting the laminated layers into a presser machine for hot pressing at a curing temperature ranging from 100° C.-400° C. and a curing pressure ranging from 10 Kg/cm²-65 Kg/cm² to obtain the circuit substrate.

11. The manufacturing method of the circuit substrate according to claim 1, wherein the manufacturing method comprises the following steps:
providing a porous glass film wherein glass accounts for more than 45% by volume;
laminating one resin coated metal foil on each side of the glass film separately;
putting the laminated layers into a presser machine for hot pressing at a curing temperature ranging from 100° C.-400° C. and a curing pressure ranging from 10 Kg/cm²-65 Kg/cm² to obtain the circuit substrate.

12. The manufacturing method of the circuit substrate according to claim 10, wherein the pores are distributed evenly in the glass film, and the pore diameter is from 20 μm to 300 μm, and wherein the pores are manufactured by laser or mechanical or chemical etching.

13. The manufacturing method of the circuit substrate according to claim 11, wherein the pores are distributed evenly in the glass film, and the pore diameter is from 20 μm to 300 μm, and wherein the pores are manufactured by laser or mechanical or chemical etching.
